(19) United States
(12) Patent Application Publication
(10) Pub. No.: US 2018/0144560 A1
(43) Pub. Date: May 24, 2018

(54) MOTOR VEHICLE DEVICE AND SYSTEM CONTROLLER AND METHOD

(71) Applicant: GM GLOBAL TECHNOLOGY OPERATIONS LLC, Detroit, MI (US)

(72) Inventors: DANIEL P. CARLESIMO, MACOMB TOWNSHIP, AZ (US); MARCELLO V. LAZARINI, MACOMB TOWNSHIP, MI (US)

(73) Assignee: GM GLOBAL TECHNOLOGY OPERATIONS LLC, Detroit, MI (US)

(21) Appl. No.: 15/358,989

(22) Filed: Nov. 22, 2016

(51) Int. Cl. G07C 5/02; H03K 3/037; G07C 5/08

(52) U.S. Cl. CPC G07C 5/02; B60R 16/023; G07C 5/08; H03K 3/037

(57) ABSTRACT

A controller mediated system to control a motor vehicle device or system includes a switch having a switch state that is operably coupled to a controller, wherein the controller is responsive to the switch state to affect operation of the controlled device or system. The controller further includes a circuit framework. The circuit framework is operable in the presence of a malfunction of the controller to affect operation of the controlled device or system responsive to the switch state.

### TECHNICAL FIELD

This patent generally relates to controllers and control inputs for motor vehicle devices and systems, and in particular, this patent relates to apparatuses and methods to execute a control input in the presence of a controller malfunction.

### BACKGROUND

To control operation of devices and systems to enable various functionalities within a motor vehicle, a switch or a combination of switches in connection with a controller may be used. That is, switch inputs are coupled to a controller instead of being hard wired to provide control inputs directly to devices and systems. The switch provides a familiar interface, e.g., a push button, rotary, toggle or similar switch to the vehicle operator; however, this interface does not directly control the device or system. Instead, the state of the switch is ascertained to provide an input signal to a processor based controller to affect an associated action within the vehicle via the controller. This architecture provides great flexibility to the vehicle designer to implement a variety of vehicle features and functions.

Various vehicle functionalities are classified according to an Automotive Safety Integrity Level (ASIL) rating as defined in International Standards Organization (ISO) standard ISO 26262. ASIL ratings are related to “severity”, “exposure” and “controllability” in the event a given function becomes unavailable during vehicle operation. The higher the ASIL rating is, the greater the impact, the functionality has on vehicle operation. Depending on the ASIL rating, for example an ASIL B rated function, it is may be required to provide continued functionality even in the event of a controlling electronic control unit (ECU) becoming inoperative. One way of providing continued functionality is to provide redundancy.

Functional redundancy can have unintended, and potentially disruptive consequences. Consider an example where a vehicle is being operated on a sunny day when an issue develops with the body control module (BCM) controlling the exterior lights or windshield wipers. To provide compliance with ISO 26262, the BCM internal watchdog may be used to turn on the wipers and the exterior lights. The lights being on during a sunny day may not be too disruptive, but having the wiper system turned on while driving on a sunny day can be quite annoying. It is these functionality “protection mechanisms”, e.g., turning on the wipers when they are not needed, that becomes the basis for customer complaints and dissatisfaction, not that the BCM has stopped working correctly.

Future functionalities and how ISO 26262 will influence them is unpredictable. What is predictable is that an elegant, operator friendly way of complying with ISO 26262 will be required to achieve high levels of customer satisfaction. Therefore, it is desirable to provide systems and methods of preserving a level of operator control of a vehicle function even in the event of an associated controller become inoperable.

### SUMMARY

A controller mediated system to control a motor vehicle device or system includes a switch having a switch state that is operably coupled to a controller, wherein the controller is responsive to the switch state to affect operation of the controlled device or system. The controller further includes a circuit framework. The circuit framework is operable in the presence of a malfunction of the controller to affect operation of the controlled device or system responsive to the switch state.

A method of controlling a load in the presence of a controller malfunction may include detecting the controller malfunction and determining a status of the vehicle. Upon detecting a change in a switch state associated with controlling the load, providing, a load on/off signal to turn the load on or off.

### BRIEF DESCRIPTION OF THE DRAWINGS

The exemplary embodiments will hereinafter be described in conjunction with the following drawing figures, wherein like numerals denote like elements, and wherein:

FIG. 1 is a functional block diagram of a controller mediated device or system control in accordance with herein described exemplary embodiments; and;

FIG. 2 is a flow diagram illustrating a method of operating a device or system in a controller mediate device or system control in the presence of a controller malfunction in accordance with herein described exemplary embodiments.

### DETAILED DESCRIPTION

The following detailed description is merely exemplary in nature and is not intended to limit the application and uses. Furthermore, there is no intention to be bound by any expressed or implied theory presented in the preceding technical field, background, brief summary or the following detailed description. It should be understood that throughout the drawings, corresponding reference numerals indicate like or corresponding parts and features. As used herein, the terms “system” or “module” may refer to any combination or collection of mechanical and electrical hardware, software, firmware, electronic control component, processing logic, and/or processor device, individually or in any combination, including without limitation: application specific integrated circuit (ASIC), an electronic circuit, a processor (shared, dedicated, or group), memory that executes one or more software or firmware programs, a combinational logic circuit, and/or other suitable components that provide the described functionality.

Embodiments of a controller mediated device and system may be described herein in terms of functional and/or logical block components and various processing steps. It should be appreciated that such block components may be realized by any number, combination or collection of mechanical and electrical hardware, software, and/or firmware components configured to perform the specified functions. For example, an embodiment may employ various combinations of electrical components, e.g., sensors, integrated circuit components, memory elements, digital signal processing elements, logic elements, look-up tables, or the like, which may carry out a variety of functions under the control of one or more microprocessors or other control devices. In addition, those skilled in the art will appreciate that embodiments may be practiced in conjunction with any number of mechanical and/or electronic systems, and that the systems described herein are merely exemplary embodiments.

For the sake of brevity, conventional components and techniques and other functional aspects of the systems (and the individual operating components of the systems) may not be described in detail herein. Furthermore, the connecting lines shown in the various figures contained herein are intended to represent example functional relationships and/or physical couplings between the various elements. It should be noted that many alternative or additional functional relationships or physical connections may be present in various embodiments.

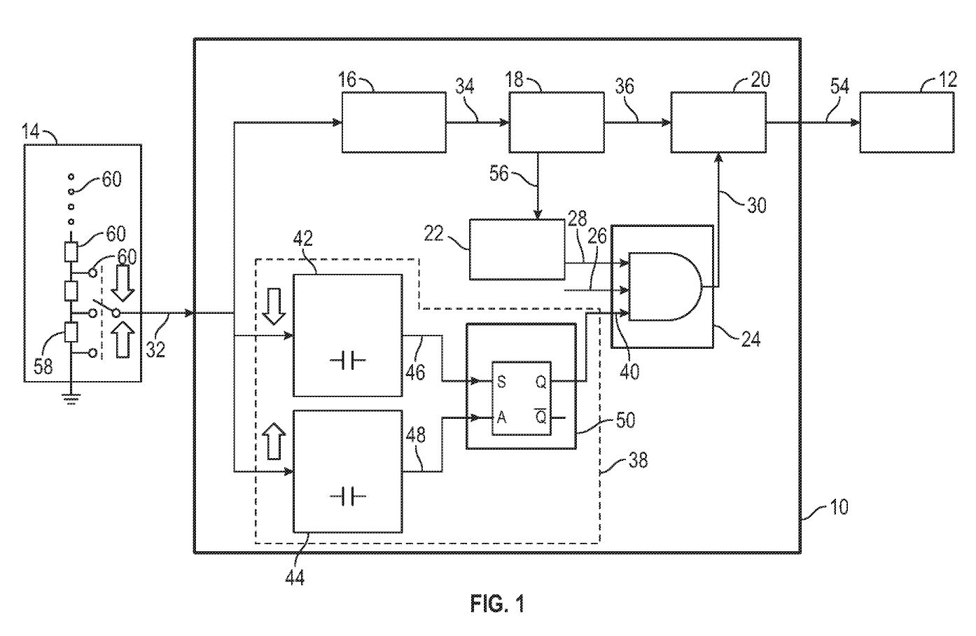

Referring to FIG. 1, a controller 10 is coupled to a load 12 and to a switch 14. The load 12 may be a device or system within a motor vehicle (not depicted), such as lights or a lighting system, windshield or rear glass wiping systems, windshield or rear glass defogging systems, and the like.

The Switch 14 may be a single or multiple position switch configured to indicate when activated a higher voltage output (positive pulse) than when deactivated (negative pulse) or other similar device capable of providing an indication of one or more requested operating states of the load 12. As depicted in FIG. 1, the switch 14 has at least three (3) positions, but the switch 14 could have more positions, and in addition to discrete positions as depicted, the switch 14 could may have a continuously variable output between a first state and a second state as is frequently found in connection with setting a delay period of an intermittent mode of wiper system operation or a brightness level of interior lights provided that at a basic level it is capable of providing the described positive pulse and negative pulse indications.

The controller 10 includes switch interface module 16 operably coupled to a processor 18, which in turn is coupled to an output module 20. The controller 10 is further coupled to a watchdog 22, which monitors a functional status of the processor 18. The processor 18 may include or be coupled to memory (not depicted) within which a set of non-transitory instructions is retained to control the operation of the controller 10 to affect a variety of functions, as is known. The controller 10 further includes an enable port 24 that receives an output 28 of the watchdog and a vehicle status signal 26, e.g., run/accessory/off, which provides an enable signal 30 to the output module 20. The enable port 24 may be implemented as a three input AND gate, providing a high (1) output to the output module 20 when all three inputs are high (1).

The switch interface module 16 has an input 32 that is coupled, via wired, wireless, fiber or other suitable coupling (not depicted), to the switch 14. The switch interface module 16 is operable to determine a state of the switch 14. This can be accomplished by periodically interrogating the switch 14, sensing a position or state of the switch 14, or be any suitable method of determining the state of the switch 14. The switch interface module 16 communicates switch data 34 relating the state of the switch 14 to the processor 18. The processor 18, in turn, is operable on the switch state data 34 to determine a desired mode of a coupled device or system and to provide mode actuation data 36 to the output module 20, which in turn, communicates the mode actuation data 36 in suitable form to the device or system, i.e., load 12, to affect operation of the load 12.

The controller 10 further includes a circuit framework 38. The circuit framework 38 is coupled to the input 32. The circuit framework 38 additionally has an output 40 coupled via the enable port 24 to the output module 20. The circuit framework 38 advantageously provides “pulse detection” without complex hardware and fine calibration as compared to “state detection,” which would be another, although less desirable way to have redundancy in a switch. In accordance with herein described embodiments, a controller is supplied with one or more redundancy protection capable inputs from a switch, such as switch 14, that indicates when activated a higher voltage output (positive pulse) than when deactivated (negative pulse) regardless of internal configuration.

Within the circuit framework 38, are a high pulse detector 42 and a low pulse detector 44. The high pulse detector 42 has an output 46 coupled to the “S” port of a R/S flip flop 50. The low pulse detector 44 has an output 48 coupled to the “R” port of the R/S flip flop 50. As arranged, the high pulse detector 42 and the low pulse detector 44 detect changes in position of the switch 14 as high/low going pulses. In the arrangement according to the exemplary embodiment depicted in FIG. 1, the R/S flip flop 50 output 40 is the latched high/low corresponding to the detected high (1) or low (0) pulses, i.e., the switch 14 state.

The watchdog 22 sets a watchdog output 28 indicative of a state of the processor 18, low (0) for normal operation and high (1) for malfunction. In normal operation of the controller 10, the circuit framework 38 and the enable port 24 are passive. In one embodiment, the vehicle status signal 26 is high (1) when the vehicle is an operating status, else it is low (0). In normal operation of the controller 10, the watchdog 22 output 28 is low (0), which will hold the enable port 24 output 30 low (0) regardless of the output 40 of the circuit framework 38.

Should the processor 18 enter a malfunction mode, the watchdog output 28 becomes high (1). With the vehicle status signal 26 high (1), indicating the vehicle is on the appropriate power mode state for the feature to be allowed, the enable port 24 is responsive to the output 40 of the circuit framework 38 to change between low (0) and high (1). The output 40 being coupled to the output module 20 causes the output module 20 to provide a rudimentary on/off signal 54 to the load 12. In this regard, the circuit framework 38 becomes operable in the presence of a processor 18 malfunction, to provide at least on/off control of the load 12.

In the herein described exemplary embodiment, the high pulse detector 42, the low pulse detector 44 and the R/S flip flop 50 operate to detect a change in the state of the switch 14. Responsive to the change in state of the switch 14 it becomes possible to control the load 12, at least at an on/off level of control. It will be appreciated that other suitable discrete circuit elements, integrated circuit elements and combinations thereof may be provided to form the circuit framework 38 to be operable to detect the change in switch 14 state and to provide at least an on/off signal to the load 12.

It will also be appreciated that the switch 14 may be a multi-position switch, as indicated in FIG. 1 of an exemplary embodiment. In this case, the multi-position switch 14 has an “off” position 58 and a plurality 60 of “on” positions. The circuit framework 38 is operable to latch the output 40 as low (0) when the switch 14 is in the off position 58, and to latch the output 40 as high (1) when the switch 14 is any of the on positions 60.

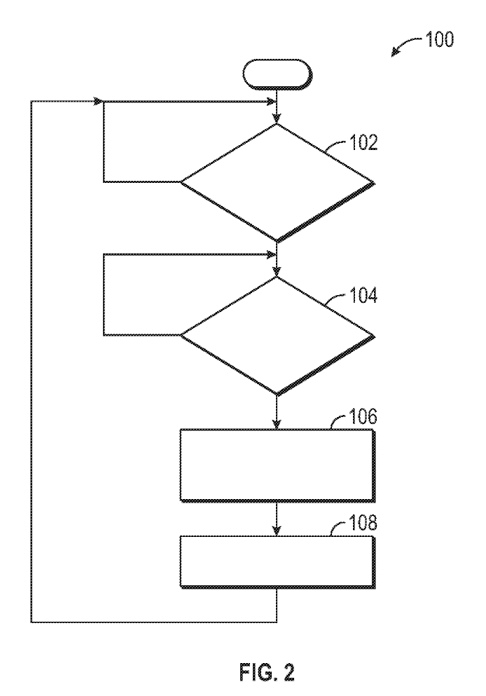

With reference to FIG. 2, a method 100 of controlling a load 12 in the presence of a controller 10 malfunction, may include determining 102 a status of the vehicle, and detecting 104 the controller 10 malfunction. Upon detecting 106 a change in a switch 14 state associated with controlling the load 12, providing 108 a load on/off signal to turn the load 12 on or off.

In the method 100, detecting a change in the switch 14 state may include detecting a high (1) or low (0) pulse, and latching the high (1) and low (0) pulse as the switch state. The method 100 may further include providing a vehicle status signal 26 and/or a controller status signal 56, with the load on/off signal 30 being responsive to one or both of the vehicle status signal 26 and the controller status signal 56.

While at least one exemplary embodiment has been presented in the foregoing detailed description, it should be appreciated that a vast number of variations exist. It should also be appreciated that the exemplary embodiment or exemplary embodiments are only examples, and are not intended to limit the scope, applicability, or configuration of the disclosure in any way. Rather, the foregoing detailed description will provide those skilled in the art with a convenient road map for implementing the exemplary embodiment or exemplary embodiments. It should be understood that various changes can be made in the function and arrangement of elements without departing from the scope of the disclosure as set forth in the appended claims and the legal equivalents thereof.

What is claimed is:

1. A controller mediated system to control a motor vehicle device or system, wherein the controller mediate system comprises:
a switch having a switch state that is operably coupled to a controller,
the controller including a processor and memory, the memory containing non-transitory instructions for the operation of the processor, such that the controller is responsive to the switch state to affect operation of a controlled device or system, and
a circuit framework, the circuit framework being operable in the presence of a malfunction of the processor to detect the state of the switch and to affect operation of the controlled device or system responsive to the state of the switch.

2. The system of claim 1, the circuit framework comprising a latch, the latch having an output corresponding to the state of the switch.

3. The system of claim 1, the circuit framework comprising a switch state detection circuit coupled to a latch circuit, the latch having an output corresponding to the state of the switch.

4. The system of claim 3, the latch comprising a flip flop circuit.

5. The system of claim 3, the switch state detection circuit comprising a pulse detector.

6. The system of claim 1, the controller comprising a watchdog, the watchdog having an output indicative of a state of the controller, the circuit framework being responsive to the output of the watchdog.

7. The system of claim 1, the controller comprising an enable port, the enable port having a first input corresponding to a status of the controller, a second input corresponding to a power mode of the vehicle and a third input corresponding to an output of the circuit framework, and an output coupled to the load.

8. The system of claim 7, the enable port comprising a three input AND gate.

9. The system of claim 1, the switch comprising a multi-position switch, at least one position corresponding to the load being off and a plurality of positions corresponding to operating modes of the load, wherein each of the plurality positions correspond to a state of the switch being on.

10. In a motor vehicle, a controller mediated load control comprising:
a switch operable to provide an indication of a desired state of the load, and
a controller operable to control the motor vehicle load responsive to the indication, and in the presence of a controller malfunction, the controller being further operable to:
detect the controller malfunction,
determine a status of the vehicle,
determine the indication of the switch, and
provide a load on/off signal to turn the load on or off responsive to the controller malfunction, the status of the vehicle and the indication.

11. The controller mediated load control of claim 10, the controller being further operable to latch a switch state corresponding to the indication.

12. The controller mediated load control of claim 10, the controller being further operable to detect a high (1) or low (0) pulse from the switch and to determine the indication from the detected high (1) or low (0) pulse.

13. The controller mediated load control of claim 12, the controller being further operable to latch the high (1) or low (0) pulse.

14. The controller mediated load control of claim 10, the controller being further operable to determine a plurality of indications of the switch, each indication corresponding to an operating mode of the load.

15. The controller mediated load control of claim 10, the controller being further operable to detect a plurality of high (1) pulses from the switch.

16. The controller mediated load control of claim 10, the controller being further operable to provide a controller status signal indicative of the controller malfunction.

17. The controller mediate load control of claim 10, comprising non-transitory computer instructions retained within a memory, the controller being operable responsive to the non-transitory computer instructions.

18. In a motor vehicle including a switch and a load, control of the load by the switch being mediated by a controller, a method of controlling a load in the presence of a controller malfunction comprising:
detecting the controller malfunction;
determining a status of the vehicle;
detecting a state of the switch; and
providing, a load on/off signal to turn the load on or off responsive to the controller malfunction, the status of the vehicle and the state of the switch.

19. The method of claim 18, wherein detecting a state of the switch comprises detecting a high (1) or a low (0) pulse from the switch.

20. The method of claim 18, further comprising latching a status of the switch.
